(19) United States
(12) Patent Application Publication
(10) Pub. No.: US 2011/0141670 A1
(43) Pub. Date: Jun. 16, 2011

(54) BACKLIGHT UNIT AND DISPLAY APPARATUS HAVING THE SAME

(75) Inventor: Kyung-ock JEONG, Suwon-si (KR)

(73) Assignee: SAMSUNG ELECTRONICS CO., LTD., Suwon-si (KR)

(21) Appl. No.: 12/856,187

(22) Filed: Aug. 13, 2010

(30) Foreign Application Priority Data
Dec. 16, 2009 (KR) 10-2009-0125311

(51) Int. Cl. H05K 7/00; F21V 21/00

(52) U.S. Cl. 361/679.01; 362/633

(57) ABSTRACT

Disclosed are a backlight unit and a display apparatus the apparatus including: a cover unit; a video receiver receiving a video signal; a video processor processing the video signal; a display panel in the cover unit which displays an image based on the processed video signal; a light guide plate in the cover unit; a plurality of light sources arranged along a lateral side of the light guide plate emitting light toward the lateral side of the light guide plate; a module substrate disposed at an edge of the cover unit, wherein the plurality of light sources are mounted on the module substrate; and a support member including a first end part coupled to the cover unit and a second end part supporting the module substrate, wherein the module substrate is not coupled to the cover unit.

### CROSS-REFERENCE TO RELATED APPLICATION

This application claims priority from Korean Patent Application No. 10-2009-0125311, filed on Dec. 16, 2009 in the Korean Intellectual Property Office, the disclosure of which is incorporated herein by reference.

### BACKGROUND

1. Field

Apparatuses and methods consistent with the present invention relate to a backlight unit that uses a light source and a light guide plate to emit light for displaying an image, and a display apparatus having the same, and more particularly, to a backlight unit having an improved structure for supporting a light source module that emits light, and a display apparatus having the same.

2. Description of the Related Art

A display apparatus includes a display panel where an image is displayed, and is capable of processing a broadcasting signal or video data of various formats, e.g., to be displayed, which can be achieved by a television (TV), a monitor, etc. The display panel may be realized by various configurations such as a liquid crystal display panel, a plasma display panel, or the like, according to its characteristics, and is applied to diverse display apparatuses. If the liquid crystal display panel cannot generate light by itself, the display apparatus may include a backlight unit that generates and emits light to the display panel.

The backlight unit of the display apparatus may employ a light emitting diode (LED) as a light source for generating light, since it is energy efficient, has a fast response time, etc. The backlight unit is classified into a direct type and an edge type according to relative positions of a light source to a light guide plate.

In the case of the direct-type backlight unit, a light source is typically arranged in parallel with, and along a rear surface of, the light guide plate, so that the light source can directly emit light toward the display panel placed in front thereof. On the other hand, in the case of the edge-type backlight unit, a light source may be arranged in the form of a bar along the edges of the light guide plate, so that light from the light source can enter the edge of the light guide plate, and from there, be projected toward the display panel. Since the light source of the edge-type backlight unit is arranged at the edge of the light guide plate, it is possible that the edge-type backlight unit may be slimmer than the direct-type backlight unit. Still, there is a desire to make even slimmer display panels.

Additionally, related art display panels may not utilize space effectively, for example, along the light source bar, or more generally, within the display panel itself. Consequently, there is also a need for a better utilization of space within the display panel.

### SUMMARY

Exemplary embodiments of the present invention may overcome the above disadvantages and other disadvantages not described above. Also, the present invention is not required to overcome the disadvantages described above, and an exemplary embodiment of the present invention may not overcome any of the problems described above.

The foregoing and/or other aspects may be achieved by providing a display apparatus including: a cover unit; a video receiver which receives a video signal; a video processor which processes the video signal received by the video receiver; a display panel which is accommodated in the cover unit and displays an image based on the video signal processed by the video processor; a light guide plate which is accommodated in the cover unit and disposed so that light is emitted toward the display panel; a plurality of light sources which are arranged along a lateral side of the light guide plate and emit the light toward the lateral side of the light guide plate; a module substrate disposed at an edge region of the cover unit, wherein the plurality of light sources are mounted on the module substrate; and a support member which includes a first end part coupled to the cover unit and a second end part supporting the module substrate, wherein the module substrate is not coupled to the cover unit

The module substrate may include no fastening hole for a fastener.

The first end part of the support member may be fastened to the cover unit by a fastener.

The fastener may be a screw.

The module substrate may be arranged to stand in parallel with the lateral side of the light guide plate.

The second end part of the support member supporting the module substrate may include a width smaller than an interval between the light sources adjacent to each other.

The support member may be bent so that the first end part of the support member is fastened to a bottom surface of the cover unit supporting a bottom of the light guide plate and the second end part of the support member supports the module substrate against a lateral wall of the cover unit standing from the bottom surface of the cover unit.

Another aspect of the present invention provides a backlight unit for irradiating a display panel, the backlight unit including: a cover unit; a light guide plate which is accommodated in the cover unit and placed on a rear of the display panel so that light is emitted toward the display panel; a plurality of light sources which are arranged along a lateral side of the light guide plate and emit the light toward the lateral side of the light guide plate; a module substrate disposed at an edge region of the cover unit, wherein the plurality of light sources are mounted on the module substrate; and a support member which comprises a first end part coupled to the cover unit and a second end part supporting the module substrate, wherein the module substrate is not fastened to the cover unit.

Another aspect of the present invention provides a display apparatus including: a cover unit; a video receiver which receives a video signal; a video processor which processes the video signal received by the video receiver; a display panel which is accommodated in the cover unit and displays an image based on the video signal processed by the video processor; a light guide plate which is accommodated in the cover unit; a plurality of light sources which are arranged along a lateral side of the light guide plate and emit light toward the lateral side of the light guide plate; a module substrate disposed at an edge region of the cover unit, wherein the plurality of light sources are mounted on the module substrate; and a support member which includes a first part coupled to the cover unit and a second part, wherein the module substrate is disposed on the second part and the first end part is coupled to the cover unit by a fastener.

### BRIEF DESCRIPTION OF THE DRAWINGS

The above and/or other aspects will become apparent and more readily appreciated from the following description of the exemplary embodiments, taken in conjunction with the accompanying drawings, in which:

FIG. 1 is an exploded perspective view of a display apparatus according to an exemplary embodiment;

FIG. 2 is a partial perspective view showing a support configuration of a module substrate when the display apparatus is assembled;

FIG. 3 is a partial perspective view showing a support member supports the module substrate in the display apparatus;

FIG. 4 is a lateral cross-section view of the display apparatus;

FIG. 5A illustrates a related art module substrate;

FIG. 5B illustrates a module substrate according to an exemplary embodiment; and

FIG. 6 is a control block diagram of a display apparatus according to an exemplary embodiment.

### DETAILED DESCRIPTION OF EXEMPLARY EMBODIMENTS

Below, exemplary embodiments will be described in detail with reference to accompanying drawings. In the following exemplary embodiments, only elements directly related to the spirit of the invention will be described, but descriptions about the other elements are omitted. However, it does not mean that the omitted elements are not necessary for embodying the display apparatus to which the spirit of the invention is applied.

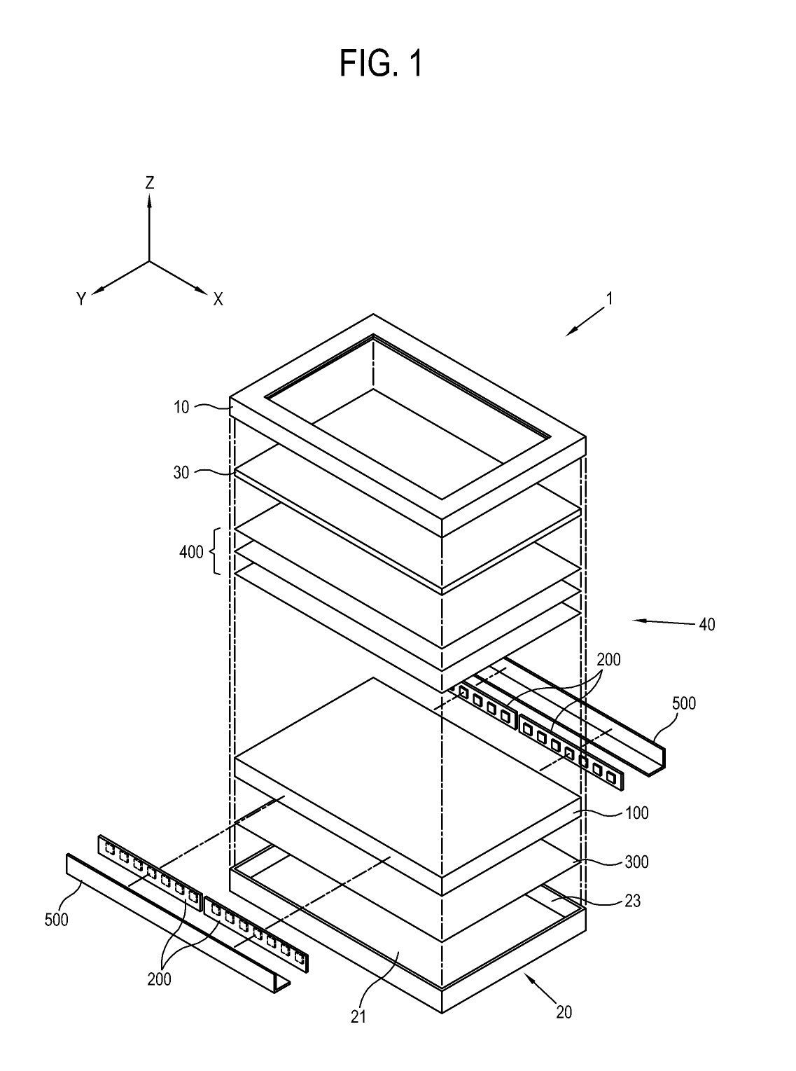

FIG. 1 is an exploded perspective view schematically showing a display apparatus according to an exemplary embodiment.

As shown in FIG. 1, a display apparatus 1 according to this exemplary embodiment includes a cover unit 10, 20 forming an accommodating space, a display panel 30 accommodated in the accommodating space of the cover unit 10, 20 and displaying an image, and a backlight unit 40 accommodated in the accommodating space and emitting light toward the display panel 30 so that an image can be shown on the display panel 30.

Directions shown in FIG. 1 are as follows. X, Y and Z directions refer to length, breadth and height directions, respectively. The display panel 30 may be located on an X-Y plane, and the backlight unit 40 and the display panel 30 are arranged as being stacked along the Z direction. Below, drawings including FIG. 1 and exemplary embodiments will be described on the basis of directions defined above. Here, opposed directions of the X, Y and Z directions are represented as −X, −Y and −Z directions, and the X-Y plane means a plane formed by the X and Y directions.

The cover unit 10, 20 form an outer appearance of the display apparatus 1, and accommodate the display panel 30 and the backlight unit 40 therein. The cover unit 10, 20 include an upper cover 10 and a lower cover 20 to cover the top of the display panel 30 and the bottom of the backlight unit 40, respectively.

The upper cover 10 and the lower cover 20 form the accommodating space in which the display panel 30 and the backlight unit 40 are accommodated. The upper cover 10 has a surface parallel with the X-Y plane and formed with an opening through which a display area of the display panel 30 is exposed.

The lower cover 20 may be opened upward in the Z direction to accommodate the backlight unit 40. The backlight unit 40 may be placed on a bottom surface 21 of the lower cover 20 in the Z direction, and supported by lateral walls standing as extended from the bottom surface 21 in the Z direction.

The display panel 30 in this exemplary embodiment may be achieved by a liquid crystal display (LCD) panel. The display panel 30 may be filled with a liquid crystal layer (not shown) between two substrates (not shown), and displays an image as the molecular arrangement of the liquid crystal layer (not shown) is varied in response to a driving signal. The display panel 30 cannot emit light by itself, and receives light from the backlight unit 40 in order to show an image on the display area. Here, the display area means an area disposed in parallel with the X-Y plane and displaying an image thereon.

The display panel 30 includes a driving circuit board (not shown), so that the molecular arrangement of the liquid crystal layer can be rotated at a predetermined angle when receiving the driving signal from the driving circuit board. Thus, optical transmissivity of cells (not shown) constituting the display area of the display panel 30 is varied with regard to each cell, thereby displaying an image on the display area.

The backlight unit 40 may be disposed on the rear or bottom of the display panel 30 so as to emit light toward the display panel 30. The backlight unit 40 includes a light guide plate 100 through which light is emitted toward the display area of the display panel 30, a light source module 300 placed in an edge region of the display apparatus 1 and generating and emitting light toward the lateral sides of the light guide plate 100, a reflective plate 300 placed on the bottom of the light guide plate 100 and reflecting light toward the display panel 30, an optical sheet 400 adjusting characteristics of the light emitted from the light guide plate 100, and an intermediate bracket 500 interposed between the light source module 200 and the lower cover 20.

The light guide plate 100 may be plastic achieved by an acrylic molding or the like, which uniformly transmit incident light from the light source module 200 to the whole display area of the display panel 30. In this exemplary embodiment, the light guide plate 100 has a size and shape corresponding to the display panel 30 and is stacked on the lower cover 20.

The light guide plate 100 may be formed with a light guiding pattern or an optical pattern on a bottom surface facing the reflective plate 300, thereby enhancing uniformity of light emitted from the light guide plate 100 and adjusting the emitted amount of light. That is, the brightness of the display area may be varied depending on what optical pattern the light guide plate 100 has.

The light source module 200 generates light to irradiate the display panel 30. The light source module 200 is placed in the edge regions of the backlight unit 40 along the lateral sides of the light guide plate 100. At this time, the light source module 200 is arranged standing so that light generated by the light source module 200 can enter the lateral sides of the light guide plate 100.

According to this exemplary embodiment, the light source module 200 is positioned in the edges of the light guide plate 100 in the Y and −Y directions. In other words, the number or the position of the light source module 200 are not limited.

The light generated by the light source module 200 is emitted toward the light guide plate 100 in the Y or −Y direction, and then emitted from the light guide plate 100 in the Z direction, thereby entering the display panel 30. Thus, the display panel 30 can show an image on the display area parallel with the X-Y plane.

The reflective plate 300 is placed on the rear or bottom of the light guide plate 100, and reflects the light from the light guide plate 100 toward the display panel 30.

At least one sheet of the optical sheet 400 is provided on the rear of the display panel 30 while being in parallel with the display panel 30. The optical sheet 400 may include a prism sheet, a diffusion sheet, a protection film, etc. and transmits light to the display panel 30 while adjusting characteristics of the light diffused by a diffusion plate 400.

The intermediate bracket 500 may be provided at the edge regions of the lower cover 20 so as to be in contact with the light source module 200. The intermediate bracket 500 includes a metallic material having high thermal conductivity to thereby efficiently discharge heat generated in the light source module 200.

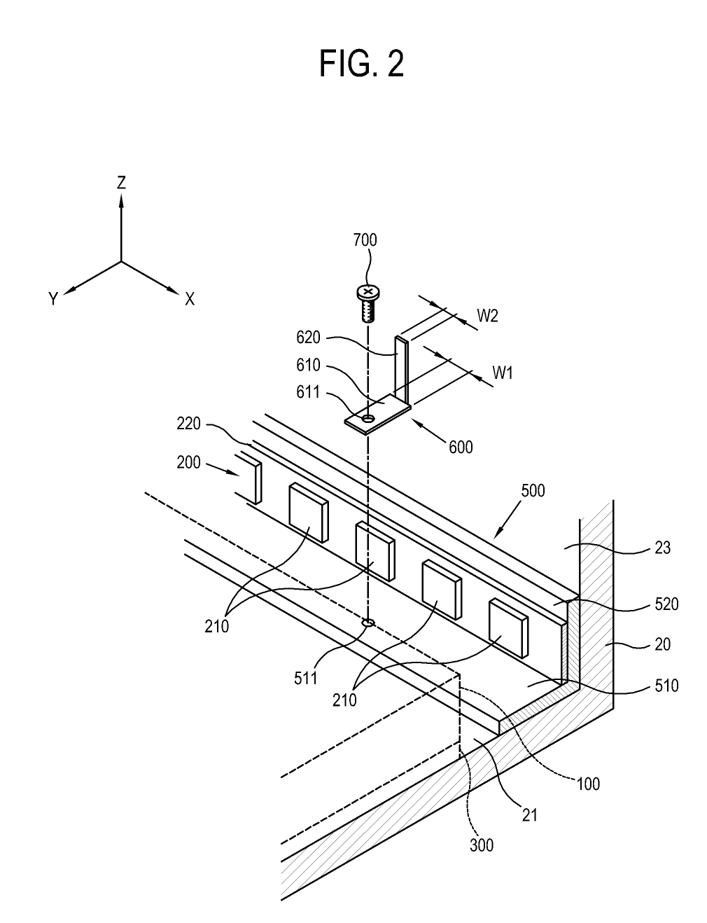

Below, an assembled configuration of the display apparatus 1 will be described with reference to FIG. 2. FIG. 2 is a partial perspective view showing the edge region in the −Y direction when the display apparatus 1 is assembled.

As shown in FIG. 2, the light source module 200 is extended in the X direction along the lateral wall 23 of the lower cover 20. The light source module 200 includes a plurality of light sources 210 generating light and irradiating the lateral side of the light guide plate 100, and a module substrate 220 to which the plurality of light sources 210 are mounted. The plurality of light sources 210 are sequentially arranged in the X direction.

The light source 210 may be achieved by a light emitting diode (LED) and mounted on the module substrate 220. The light source 210 receives driving power and an on/off control signal from the module substrate 220. Here, each light source 210 included in the light source module 200 has the same direction for emitting light.

The light source 210 mounted to the module substrate 220 may include a blue LED, a green LED and a red LED, and thus blue light, green light and red light emitted from the respective colorful LEDs are mixed to generate white light for good color reproduction. However, the light source 210 may also include a white LED capable of directly generating the white light.

The module substrate 220 has a wiring configuration (not shown) for supplying power from system power for the display apparatus 1 to the mounted light source 210. The plurality of light sources 210 on the module substrate 220 forms a plurality of groups, and the foregoing wiring configuration supplies power to individual groups to thereby accomplish local dimming for selectively controlling the plurality of light sources 210 to be turned on/off.

The module substrate 220 stands (i.e., is disposed) on the bottom surface 21 and being in parallel with the lateral wall 23. The module substrate 220 is extended in the X direction like the arranged direction of the plurality of light sources 210. Thus, the light sources 210 are mounted on the module substrate 220 standing as described above, so that the light sources 210 can emit light in the Y direction.

The light guide plate 110 is placed in front of the light source 210 in Y direction, and the light emitted from the light source 210 enters the lateral side of the light guide plate 100.

Meanwhile, the intermediate bracket 500 may be interposed between the module substrate 220 and the lower cover 20. The intermediate bracket 500 may be extended in the X direction along a bent region where the bottom surface 21 and the lateral wall 23 of the lower cover 20 meet each other. The intermediate bracket 500 includes a first bracket surface 510 contacting the bottom surface 21, and a second bracket surface 520 contacting the lateral wall 23.

With this configuration, there a configuration for coupling the module substrate 220 to the intermediate bracket 500 and the lower cover 20 may be needed. In the related art, there has been proposed a configuration where the module substrate 220 may be directly fastened to the lower cover 20 by a screw. However, in such a related art configuration, a fastening hole may be needed to couple the screw with the module substrate 220, so that it may be disadvantageous to form the wiring configuration on the module substrate 220 in light of discharging heat and reducing the width of the module substrate 220. It should be noted that the terms “fastened” and “coupled” (and the like) are used interchangeably herein.

According to an exemplary embodiment, the display apparatus 1 includes a support member 600 having first end part coupled to the lower cover 20 and a second end part supporting the module substrate 220 to the lower cover 20. Thus, it is possible to support the module substrate 220 without forming a fastening hole for fastening the screw to the module substrate 220.

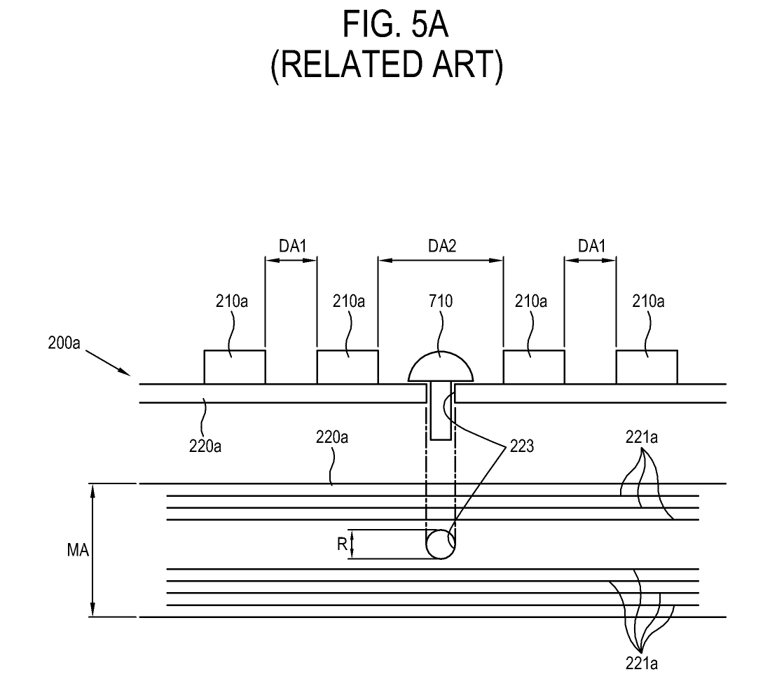

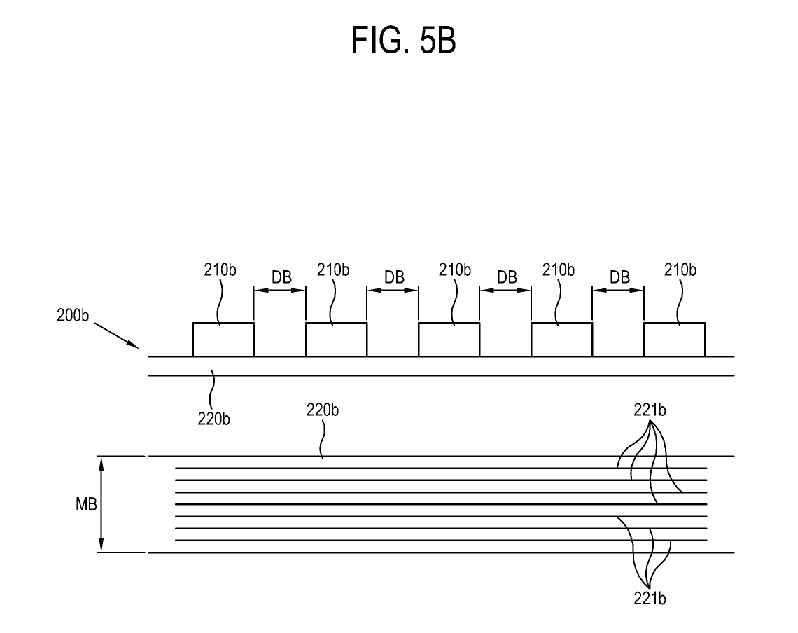

It should be noted that although FIGS. 2 and 5 depict the “hole” as being a circular hole, the present invention is not limited thereto. Instead, the term “hole” may include any type of opening (e.g., square, rectangular, triangular, oval, etc.) capable of accommodating a fastener, such as a screw or rivet, etc. Additionally, the terms “hole” and “opening” are used interchangeably herein.

The support member 600 includes a fastening part 610 extended in parallel with the bottom surface 21 and formed with a support-member fastening hole 611, and a supporting part 620 extend from the fastening part 610 and bent standing. The fastening part 610 may be fastened to the intermediate bracket 500 and the lower cover 20 by a screw 700, and the supporting part 620 supports a certain region of the module substrate 220 between two light sources 210 adjacent to each other.

Here, the fastening part 610 has a width W1 larger than the diameter of the support-member fastening hole 611 corresponding to a standard of the screw 700. The supporting part 620 has a width W2 which may be smaller than an interval between the adjacent two light sources 210. Thus, the light can be emitted from the light source 210 without being interfered by the supporting part 620.

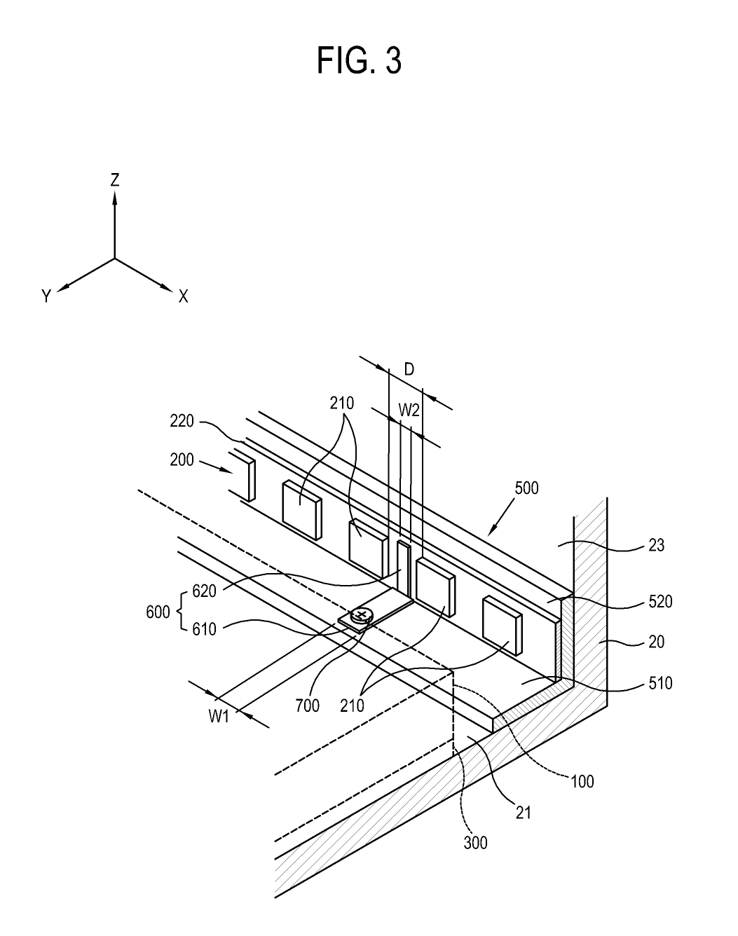

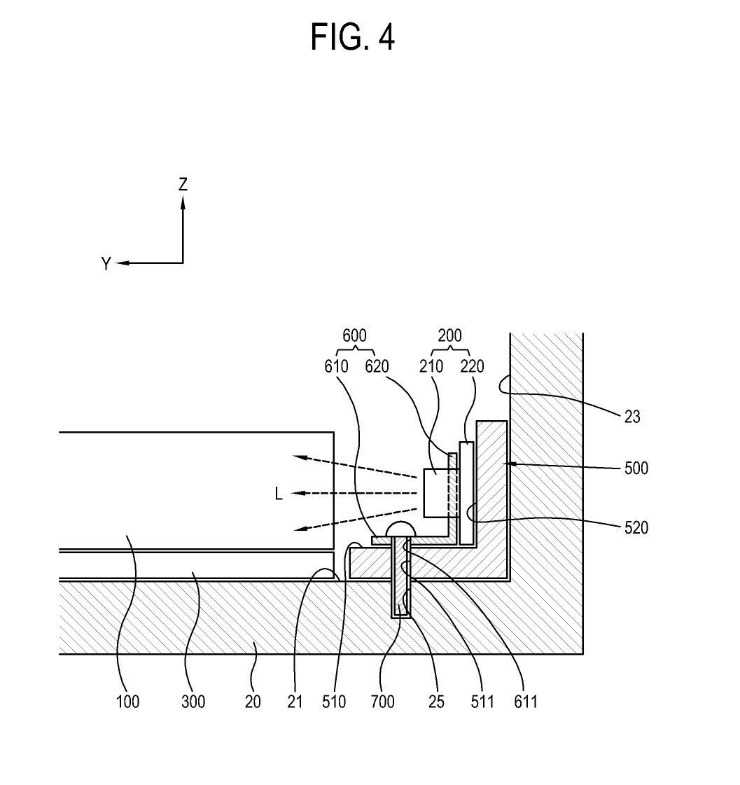

Below, the state that the support member 600 supports the module substrate 220 will be described with reference to FIGS. 3 and 4. FIG. 3 is a partial perspective view showing the support member 600 supports the module substrate 220 in FIG. 2, and FIG. 4 is a lateral cross-section view of FIG. 3.

As shown in FIGS. 3 and 4, the support member 600 may be disposed so that the fastening part 610 is placed on the first bracket surface 510 and the supporting part 620 contacts the module substrate 220 between the adjacent two light sources 210. The support-member fastening hole 611 formed on the fastening part 610 corresponds to an intermediate-bracket fastening hole 511 and a lower-cover fastening hole 25. If the screw 700 is fastened to these fastening holes 25, 511 and 611, the fastening part 610 is fastened to the intermediate bracket 500 and the lower cover 20.

It should be noted that although the intermediate bracket 500 depicted in the exemplary embodiments of FIGS. 1-4 is shown as being an integral piece, the present invention is not limited thereto. Alternative exemplary embodiments might utilize a bracket made of two or more pieces put together.

Further, although the intermediate bracket 500 depicted in the exemplary embodiments of FIGS. 1-4 is shown as having an “L” shape, the present invention is not limited thereto. For example, the bracket may have a “T”-like shape (e.g., referring to FIG. where the second bracket surface 520 is offset from the lateral wall 23).

It should further be noted that while the screw 700 in FIGS. 4, 5A and 5B are depicted as having a rounded head, the present invention is not limited thereto. The screw might also have a flat head, for example. Further, the screw 700 is merely an example of a type of fastener. However, the present invention is not limited thereto. A “fastener,” as used herein includes both threaded (e.g., a screw) and threadless (e.g., a rivet) fasteners.

In this exemplary embodiment, the fastening part 610 is fastened to both the intermediate bracket 500 and the lower cover 20 by the screw 700. However, the present invention is not limited thereto. Alternatively, a separate coupling configuration may be provided between the intermediate bracket 500 and the lower cover 20, and the screw 700 may be used to fasten the fastening part 610 to only the intermediate bracket 500.

Since, in one exemplary embodiment, the width W2 of the supporting part 620 is smaller than the interval D between the adjacent two light sources 210, the supporting part 620 can support the module substrate 220 as placed between the adjacent two light sources 210.

It should be noted that although the exemplary embodiments depicted in FIGS. 1 and 2 show W1 being larger than W2, the present invention is not necessarily limited thereto. W1 may be equal to W2, or alternatively, W1 may be smaller than W2. However, if W1 is equal to or less than W2, the interval D may not be reduced. Nevertheless, in this case, other benefits (such as described below with respect to the space utilization of the wiring lines within the module substrate) may still be realized.

The module substrate 220 stands on the bottom surface 21 as it is supported by the supporting part 620, thereby allowing the light source 210 to emit light L toward the lateral side of the light guide plate 100 in the Y direction.

Consequently, in the edge-type backlight unit 50, the module substrate 220 can be supported on the lower cover 20 by a simple structure even though the fastening hole for the screw-coupling is not formed on the module substrate 220.

Below, the module substrate 200a with the related art fastening hole 223 and a module substrate 200b without any fastening hole will be compared.

FIG. 5A is an example view for comparison between the module substrate 200b according to an exemplary embodiment and the related art module substrate 200a.

(FIG. 5A shows a cross-section view and a plan view of the module substrate 220a formed with the fastening hole 223 in the related art light source module 200a.

The plurality of light sources 210a are mounted on the module substrate 220a, and the wiring lines 221a for turning on/off the respective light source 210a are formed on the module substrate 220a along the mounting direction of the light sources 210a. The plurality of light sources 210a are grouped, and the wiring lines 221a are connected to the respective light sources 210a according to the groups, thereby selectively turning on/off the light sources 210a.

The fastening hole 223 for the screw 710 is formed on the module substrate 220a between the adjacent two light sources 210a. Here, there may be needed a space for the fastening hole 223, the screw 710 and the screw's head between the two light sources 210a, i.e., in a corresponding place where the fastening hole 223 is positioned. Thus, in light of an interval between the adjacent two light sources 210a, the interval DA2 considering the fastening hole 223 is larger than an interval DA1 considering no fastening hole.

Accordingly, the amount of light irradiated to the lateral side of the light guide plate 100 corresponding to the area where the fastening hole 223 and the screw 710 are provided is relatively small, thereby causing a dark portion.

Also, since the fastening hole 223 penetrates the module substrate 220a, it is difficult to form the wiring line 221a on the module substrate 220a within the width corresponding to the diameter R of the fastening hole 223. Accordingly, an interval between the wiring lines 221a has to be decreased, or the width MA of the module substrate 220a has to be increased, so that it may be disadvantageous to discharge heat in the former case and to make the display apparatus slim in the latter case.

On the other hand, FIG. 5B shows a cross-section view and a plan view of the module substrate 220b supported by the support member 600 according to an exemplary embodiment.

In the configuration shown in FIG. 5B, the module substrate 220b has no fastening hole. Thus, it is possible to make the interval DB between the light sources 210b uniform without considering the screw 710 and the fastening hole 223, thereby excluding a dark portion.

Also, the wiring line 221b can be arranged without taking the fastening hole into account. With respect to the same interval between the wiring lines 221b and the same number of the wiring lines 221b, the width MB of the module substrate 220b can become smaller than the width MA of the module substrate 220a. Accordingly, it is possible to make the display apparatus 1 slimmer.

Further, with regard to the same width of the module substrate 220b, the number of wiring lines 221b can be more increased as compared with that the related art configuration or the interval between the wiring lines 221b can become relatively large to be excellent in discharging heat.

Thus, according to an exemplary embodiment, the module substrate 220 is not fastened to the lower cover 20 but supported on the lower cover 20 by the support member 600, so that a local-brightness decrease on the display area can be improved and the wiring configuration for the module substrate 220 can be improved to thereby enhance a heat-radiating structure and make the display apparatus slim.

Meanwhile, in the foregoing exemplary embodiments, the intermediate bracket 500 is interposed between the light source module 200 and the lower cover 20, but not limited thereto. Alternatively, the light source module 200 may directly contact the lower cover 20 without the intermediate bracket.

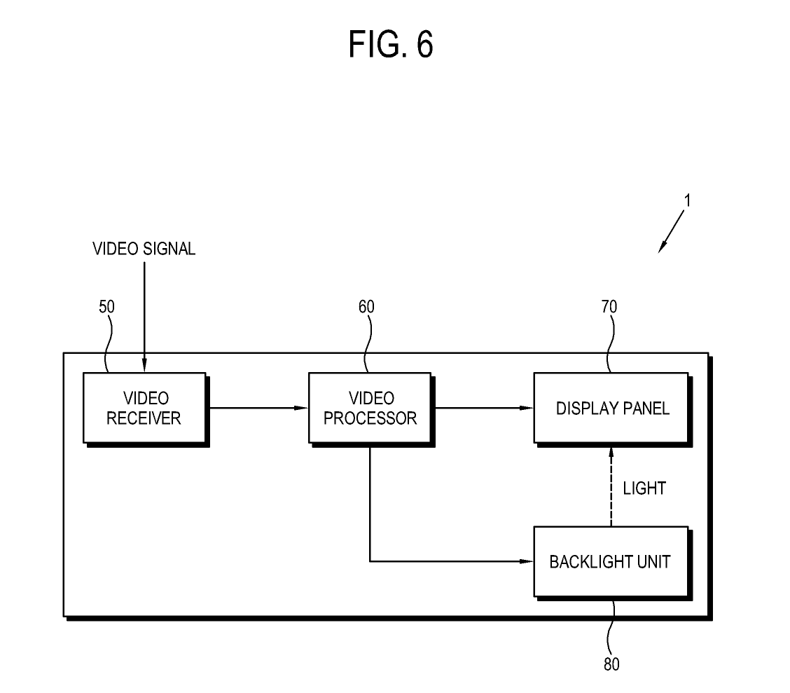

Also, the foregoing exemplary embodiments may be applied to various types of the display apparatus 1. Below, the exemplary embodiment applied to a television (TV) used as the display apparatus 1 will be described with reference to FIG. 6.

FIG. 6 is a control block diagram of the display apparatus 1 according to an exemplary embodiment. In FIG. 6, the solid lines indicate transmission of a video signal or a control signal, and the dotted lines indicate transmission of light.

As shown in FIG. 6, the display apparatus 1 according to this exemplary embodiment includes a video receiver 50 to receive a video signal, a video processor 60 to process the video signal received in the video receiver 50, a display panel 70 to display an image based on the video signal processed by the video processor 60, and a backlight unit 80 to emit light so that an image displayed on the display panel 70 cab be shown.

The video receiver 50 may have various standards as follows. For example, if the display apparatus 1 is a TV, the video receiver 60 may wirelessly receive a radio frequency (RF) signal output from a broadcasting station (not shown), or may receive a video signal based on standards such as composite video, component video, super video, SCART, High definition multimedia interface (HDMI), etc. Besides, if the display apparatus 1 is a monitor for a computer system, the video receiver 50 may receive a video signal based on standards such as a D-SUB for transmitting an RGB signal according to VGA, a digital video interactive (DVI), HDMI, etc.

The video processor 60 applies various preset video processes to the video signal transmitted from the video signal receiver 50. The kinds of video processes that can be performed in the video processor 60 are not limited. For example, the video processes may include decoding and encoding corresponding to various video formats, de-interlacing, frame refresh rate conversion, scaling, noise reduction, detail enhancement, etc.

The video processor 60 may be achieved by individual configurations capable of performing the foregoing respective processes, or may be achieved by an all-in-one configuration in which various functions are integrated.

The display panel 70 and the backlight unit 80 have the same configuration as described above, and thus repetitive descriptions thereof will be avoided.

Although a few exemplary embodiments have been shown and described, it will be appreciated by those skilled in the art that changes may be made in these exemplary embodiments without departing from the principles and spirit of the invention, the scope of which is defined in the appended claims and their equivalents.

What is claimed is:

1. A display apparatus comprising:
a cover unit;
a video receiver which receives a video signal;
a video processor which processes the video signal received by the video receiver;
a display panel which is accommodated in the cover unit and displays an image based on the video signal processed by the video processor;
a light guide plate which is accommodated in the cover unit and disposed so that light is emitted toward the display panel;
a plurality of light sources which are arranged along a lateral side of the light guide plate and emit the light toward the lateral side of the light guide plate;
a module substrate disposed at an edge region of the cover unit, wherein the plurality of light sources are mounted on the module substrate; and
a support member which includes a first end part coupled to the cover unit and a second end part supporting the module substrate, wherein the module substrate is not coupled to the cover unit.

2. The display apparatus according to claim 1, wherein the module substrate comprises no fastening hole for a fastener.

3. The display apparatus according to claim 1, wherein the first end part of the support member is fastened to the cover unit by a fastener.

4. The display apparatus according to claim 3, wherein the fastener is a screw.

5. The display apparatus according to claim 1, wherein the module substrate is arranged to stand in parallel with the lateral side of the light guide plate.

6. The display apparatus according to claim 1, wherein the second end part of the support member supporting the module substrate comprises a width smaller than an interval between the light sources adjacent to each other.

7. The display apparatus according to claim 1, wherein the support member is bent so that the first end part of the support member is fastened to a bottom surface of the cover unit supporting a bottom of the light guide plate and the second end part of the support member supports the module substrate against a lateral wall of the cover unit standing from the bottom surface of the cover unit.

8. A backlight unit for irradiating a display panel, the backlight unit comprising:
a cover unit;
a light guide plate which is accommodated in the cover unit and placed on a rear of the display panel so that light is emitted toward the display panel;
a plurality of light sources which are arranged along a lateral side of the light guide plate and emit the light toward the lateral side of the light guide plate;
a module substrate disposed at an edge region of the cover unit, wherein the plurality of light sources are mounted on the module substrate; and
a support member which comprises a first end part coupled to the cover unit and a second end part supporting the module substrate, wherein the module substrate is not fastened to the cover unit.

9. The backlight unit according to claim 8, wherein the module substrate comprises no fastening hole for a fastener.

10. The backlight unit according to claim 8, wherein the first end part of the support member is fastened to the cover unit by a fastener.

11. The backlight unit according to claim 10, wherein the fastener is a screw.

12. The backlight unit according to claim 8, wherein the module substrate is arranged to stand in parallel with the lateral side of the light guide plate.

13. The backlight unit according to claim 8, wherein the second end part of the support member supporting the module substrate comprises a width smaller than an interval between the light sources adjacent to each other.

14. The backlight unit according to claim 8, wherein the support member is bent so that the first end part of the support member is fastened to a bottom surface of the cover unit supporting a bottom of the light guide plate and the second end part of the support member supports the module substrate against a lateral wall of the cover unit standing from the bottom surface of the cover unit.

15. A display apparatus comprising:
a cover unit;
a video receiver which receives a video signal;
a video processor which processes the video signal received by the video receiver;
a display panel which is accommodated in the cover unit and displays an image based on the video signal processed by the video processor;
a light guide plate which is accommodated in the cover unit;
a plurality of light sources which are arranged along a lateral side of the light guide plate and emit light toward the lateral side of the light guide plate;
a module substrate disposed at an edge region of the cover unit, wherein the plurality of light sources are mounted on the module substrate; and
a support member which includes a first part coupled to the cover unit and a second part, wherein the module substrate is disposed on the second part and the first part is coupled to the cover unit by a fastener.
